(19) United States
(12) Patent Application Publication
(10) Pub. No.: US 2009/0197396 A1
(43) Pub. Date: Aug. 6, 2009

(54) Method for Producing Silicon Wafer

(75) Inventor: Wei Feig Qu, Annaka (JP)

Correspondence Address: OLIFF & BERRIDGE, PLC, P.O. BOX 320850, ALEXANDRIA, VA, 22320-4850, US

(73) Assignee: Shin-Etsu Handotai Co., Ltd., Tokyo (JP)

(21) Appl. No.: 12/308,120

(22) PCT Filed: May 24, 2007
(86) PCT No.: PCT/JP2007/060601

§ 371 Date: Dec. 8, 2008

(30) Foreign Application Priority Data
Jul. 6, 2006 (JP) 2006-186591

(51) Int. Cl. H01L 21/322

(52) U.S. Cl. 438/473; 257/E21.318

(57) ABSTRACT

The present invention provides a method for producing a silicon wafer at least including a step of performing RTA heat treatment with respect to a silicon wafer in an atmospheric gas, wherein nitrogen gas is used as the atmospheric gas, which is mixed with oxygen at a concentration of less than 100 ppm so as to perform the heat treatment. Hereby a method for producing a high-quality wafer can be provided, where the RTA heat treatment subject to the silicon wafer can be performed at a low temperature or over a short period of time, so that generation of slip dislocation of the silicon wafer can be suppressed, and at the same time vacancies can be implanted inside the silicon wafer without using NH₃.

### TECHNICAL FIELD

The present invention relates to a method for producing silicon wafer by forming vacancies inside the silicon wafer by performing RTA heat treatment in an atmospheric gas so as to give gettering capacity.

### BACKGROUND ART

Silicon wafers manufactured by processing a silicon single-crystal grown by pulling with the Czochralski (CZ) method contain many oxygen impurities. These oxygen impurities form oxide precipitates (referred to as Bulk Micro Defects, hereinafter called as “BMD”) which give rise to dislocation and defects and the like. When these oxide precipitates are on the surface on which devices are formed, they cause increased leakage current and reduced oxide dielectric breakdown voltage and the like, having significant affects on the characteristics of the semiconductor device.

Conventionally, therefore a method for forming homogenously a denuded zone (DZ, i.e. a defect-free layer) has been employed. (See pamphlet of International Publication No. WO 98/38675.) That is, the surface of the silicon wafer is rapidly heated to a temperature of 1250° C. or higher and quenched (Rapid Thermal Annealing, hereinafter called as “RTA”) over a short period of time, in a prescribed atmosphere gas to form atomic vacancies (hereafter referred to simply as “vacancies”) of a high concentration and a thermal equilibrium inside the silicon wafer. Then, quenching the silicon wafer freezes the vacancies. It is then heat treated to cause outward diffusion of the vacancies on the surface of the wafer. After the formation of the above-mentioned denuded zone, by the following heat treatment at a temperature below the aforementioned temperature, oxide precipitates are nucleated and stabilized as the interior defect zone, and thus a BMD zone having a gettering effect is formed. Thus obtained silicon wafer includes denuded zones 7 on the surfaces and a BMD zone 8 inside as shown in FIG. 2.

In accordance with another prior art (in pamphlet of International Publication No. WO 98/45507, for example), heat treatment is performed under oxygen atmosphere first and then under non-oxidizing atmosphere so as to form denuded zones on the surfaces of the silicon wafer and a BMD zone inside the silicon wafer. Note that conventionally N₂ (nitrogen) is mainly used as atmospheric gas for heat treatment for forming vacancies. In other words, N₂ is decomposed at a high temperature, and then SiₓN_{y} (nitride film) is formed on the surface of the silicon wafer, so that vacancies are implanted.

In the above-mentioned heat treatment technique of silicon wafer, however, there still remains problems as follows: in order to perform heat treatment for forming vacancies, for example, the heat treatment is performed conventionally in an atmospheric gas mainly consisting of N₂, wherein it needs to be performed at 1250° C. or above for 10 seconds or longer for obtaining sufficient effect of heat treatment.

Therefore, a silicon wafer often suffers from generation of slip dislocation at the positions contacting with a susceptor or a supporting pin due to high-temperature heat treatment, which cause cracking and the like. There is also another problem of causing rough surface because a natural oxide film, which had been more or less formed prior to the heat treatment on the surface of the silicon wafer, is sublimed due to a high temperature.

Japanese Patent Application Laid-open No. 2003-31582 proposes that as atmospheric gas used for heat treatment for newly forming vacancies inside of the silicon wafer, an atmospheric gas containing nitride gas (such as NH₃) with a lower decomposition temperature than that of N₂ is employed. This method enables the nitride gas to be decomposed at a lower heat treatment temperature or over a shorter heat treatment time period, compared to the case with N₂, for nitriding the surface of the silicon wafer, and accordingly vacancies can be implanted inside. Generation of slip dislocation at the heat treatment can be also suppressed. Accordingly, a high-quality wafer with sufficient denuded zones on the silicon wafer surfaces and with an adequately high BMD density inside can be obtained by the subsequent thermal treatment.

In this case, nitride gas containing NH₃ is preferably used as nitride gas. Hydrogen produced by the decomposition of NH₃ has a cleaning effect for removing a natural oxide film on the surface of the silicon wafer, so that nitriding on the surface and implanting of vacancies are further enhanced.

For this purpose, however, a equipment for supplying harmful NH₃ becomes necessary, which increases equipment cost. Accordingly, a method for producing a silicon wafer without using NH₃ and simultaneously providing the same quality as that in the case of using nitride gas containing NH₃ has been desired.

### DISCLOSURE OF INVENTION

The present invention has been made in view of the above-mentioned problems. An object of the invention is to provide a method for producing a high-quality silicon wafer, where a RTA heat treatment can be performed subject to the silicon wafer at a lower temperature or over a short period of time to suppress generation of slip dislocation of the silicon wafer, and at the same time vacancies can be implanted inside the silicon wafer without using NH₃.

In order to achieve the above-mentioned object, the present invention provides a method for producing a silicon wafer at least including a step of performing RTA heat treatment with respect to a silicon wafer in an atmospheric gas, wherein nitrogen gas is used as the atmospheric gas, which is mixed with oxygen at a concentration of less than 100 ppm so as to perform the heat treatment.

By thus using nitrogen gas as the atmospheric gas, which is mixed with oxygen at a concentration of less than 100 ppm so as to perform the RTA heat treatment, it is possible to form a thick oxynitride film on the surface of the silicon wafer. As this oxynitride film is formed thickly, the number of silicon atoms reacting with nitrogen increases, resulting in that the amount of vacancies which can be implanted inside the silicon wafer increases. Therefore, vacancies can be implanted inside the silicon wafer efficiently at a relatively low temperature even without using harmful gas such as NH₃ as atmospheric gas. Accordingly, by the subsequent thermal treatment a high-quality wafer with sufficient denuded zones on the surface of the silicon wafer and with an adequately high BMD density inside can be obtained.

Additionally processes of this method are simple because it is sufficient that only a small amount of oxygen, of which concentration is lower than 100 ppm, is added to the nitrogen gas. As this method does not employ harmful NH₃, a conventional furnace for RTA heat treatment can be used, so that no additional equipment cost is generated. Therefore, cost reduction can be realized in the both aspects.

Here, it is preferable that the concentration of the oxygen mixed in the nitrogen gas atmosphere is set to be from 15 ppm to 90 ppm.

By thus setting the concentration of the oxygen mixed in the nitrogen gas atmosphere from 15 ppm to 90 ppm, an oxynitride film can be formed thick enough and thicker on the surface of the silicon wafer than a nitride film formed by N₂ gas, so that oxygen precipitation can be enhanced by way of implanting vacancies.

The heat treatment can be performed at a temperature of 1100° C. or more and 1250° C. or less, and over a period of time from 1 to 60 sec. In the present invention, as the heat treatment can be performed as mentioned-above at a temperature of 1100° C. or more and 1250° C. or less, and over a period of time from 1 to 60 sec, i.e., at a relatively low temperature and over a relatively short period of time than in the case using only N₂ gas. Therefore, generation of slip dislocation can be suppressed and at the same time enough vacancies can be implanted inside the silicon wafer so that a BMD zone with an adequately high BMD density can be obtained.

It is also preferable in the present invention that oxygen concentration of the silicon wafer before being subject to the heat treatment is set to be from 9 ppma to 12 ppma (JEITA).

If oxygen concentration of the silicon wafer before being fed into a furnace for the heat treatment is thus set to be from 9 ppma to 12 ppma (JEITA), an adequate amount of precipitated oxygen can be obtained through RTA heat treatment, and generation of slip dislocation at the heat treatment can be suppressed. Accordingly, a high-quality wafer with sufficient denuded zones on the surfaces of the silicon wafer and with BMD zone having an adequately high BMD density inside the silicon wafer can be obtained by the subsequent thermal treatment.

As the method of the present invention does not employ harmful NH₃ as atmospheric gas for the RTA heat treatment, without increasing the cost for equipment, the surface of the silicon wafer can get an oxynitride film at a relatively low temperature and vacancies can be implanted inside as well. Generation of slip dislocation at the heat treatment can be also suppressed. Accordingly, a high-quality wafer with sufficient denuded zones on the silicon wafer surfaces and with a BMD zone having an adequately high BMD density inside can be obtained by the subsequent thermal treatment.

### BRIEF DESCRIPTION OF THE DRAWINGS

FIG. 1 is a schematic view showing an example of a furnace for heat treatment used in a method for producing a silicon wafer of the present invention.

FIG. 2 is a schematic view showing denuded zones and a BMD zone of the silicon wafer.

FIG. 3 is a graph showing a relation between the thickness of a nitride film formed on the silicon wafer by a conventional RTA heat treatment and its distance from the center of the silicon wafer.

FIG. 4 shows observation results, by XRT, of a nitride film or an oxynitride film formed on the silicon wafer by RTA heat treatment, wherein atmospheric gas at RTA heat treatment contains only N₂ in (A), N₂/small amount of O₂ (25 ppm) in (B), and N₂/small amount of O₂ (50 ppm) in (C), respectively.

FIG. 5 is a graph showing a relation between change of Oi before/after the heat treatment for oxygen precipitation following the RTA heat treatment, and oxygen concentration mixed in nitrogen gas atmosphere at the RTA heat treatment.

FIG. 6 is a graph showing a relation between BMD density and its distance from the center.

FIG. 7 shows observation results of BMD zones after performing RTA heat treatment with respect to the silicon wafer followed by three-stage heat treatment, wherein the atmospheric gas at RTA heat treatment contains only N₂ in (A), N₂/small amount of O₂ (25 ppm) in (B), and N₂/small amount of O₂ (50 ppm) in (C), respectively.

FIG. 8 consists of two graphs: (A) shows residual Oi amount and (B) shows BMD density in a depth direction, respectively, with respect to the silicon wafer having oxygen concentration of 11.3 ppma to 11.7 ppma prior to RTA heat treatment, which was then subject to RTA heat treatment, and then three-stage heat treatment.

### BEST MODE(S) FOR CARRYING OUT THE INVENTION

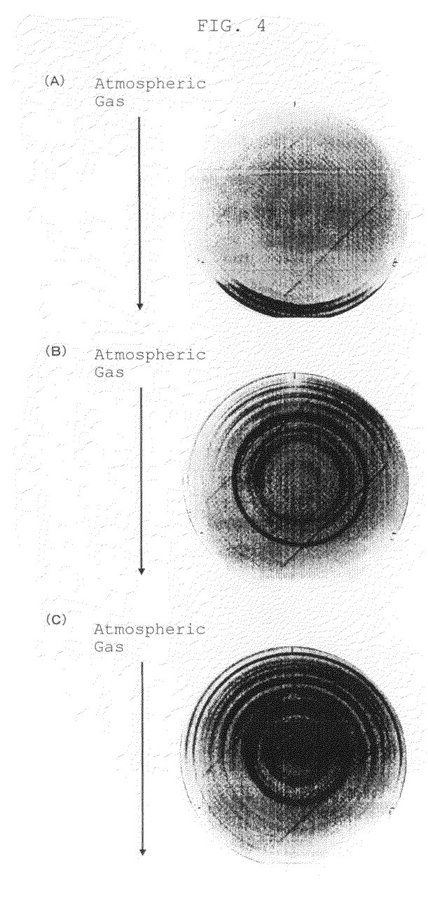

FIG. 3 is a graph showing a relation between the thickness of a nitride film formed on the silicon wafer and its distance from the center of the silicon wafer when the silicon wafer is subject to RTA heat treatment in the heat treatment furnace, where nitrogen gas or mixed gas of NH₃ and Ar were supplied as atmospheric gas.

The inventor of the present invention has found from the graph in FIG. 3, that a nitride film having a thickness of 26 to 28 Å was formed almost homogenously from the gas inlet side to outlet side on the silicon wafer, when mixed gas with NH₃ and Ar was used as atmospheric gas for the RTA heat treatment. On the other hand, he found that in the case of using only N₂ gas as atmospheric gas at RTA heat treatment, though the nitride film formed on the silicon wafer surface had almost homogenous thickness with 12 to 14 Å in the direction perpendicular to the atmospheric gas flow on the wafer surface, it had a greater thickness in the direction from the inlet side to the outlet side in the flow direction of the atmospheric gas. By examining the nitride film formed on the silicon wafer surface at the gas outlet side, the inventor has found that a oxynitride film (SiNₓO_{y}) was formed there, which they assumed to be generated due to a small amount of oxygen leak at the gas outlet side, as described with reference to FIG. 1 below.

He also found that the amount of precipitated oxygen was much at the region where the oxynitride film was formed, and that BMD size was smaller, and accordingly that more vacancies were implanted.

Therefore, the inventor of the invention found that by positively supplying nitrogen gas mixed with a small amount of oxygen as atmospheric gas for RTA heat treatment into the heat treatment furnace, a thick oxynitride film could be formed on the entire surface of the silicon wafer, and accordingly that enough vacancies could be implanted inside the wafer, resulting that sufficient denuded zones could be formed on the silicon wafer surfaces and high BMD density could be realized inside the silicon wafer by the subsequent thermal treatment. Then the inventor has completed the invention.

Below, the present invention will be described with reference to embodiments, although the present invention is not limited to these embodiments.

First, an example of a RTA heat treatment furnace used for the present invention is shown in FIG. 1. The heat treatment furnace may be substantially the same as a conventional heat treatment furnace. The heat treatment furnace 1 has a lid 9 for covering a feed-in opening of a silicon wafer 6, a gas inlet 2 for feeding atmospheric gas, a gas outlet 3 for discharging the atmospheric gas, a susceptor 4 for placing the silicon wafer 6, and a lamp 5 for heating the silicon wafer 6. As a small amount of oxygen leaks in from the gap between the lid 9 and the heat treatment furnace 1, formed atmosphere contains a small amount of oxygen only in a limited area of the gas outlet side. In the present invention, N₂ (nitrogen) mixed with a small amount of O₂ (oxygen) with less than 100 ppm is fed into the heat treatment furnace as atmospheric gas, and then onto the entire surface of the wafer.

For performing RTA heat treatment with respect to the silicon wafer 6 in the heat treatment furnace 1, the silicon wafer 6 is placed on the susceptor 4. The above-mentioned atmospheric gas (N₂/small amount of O₂) is fed from the gas inlet 2 onto the surface of the silicon wafer 6, and the silicon wafer is subject to heat treatment with rapid heating and quenching over a short period of time, wherein heat treatment temperature is in the range of 1100 to 1250° C. and a heat treatment time period is in the range of 1 to 60 sec.

FIG. 4 shows a nitride film or an oxynitride film (black color) formed on the silicon wafer surface after RTA heat treatment with a temperature of 1200° C. over a time period of 10 seconds, wherein no oxygen was contained in the nitrogen gas atmosphere in (A), 25 ppm oxygen was mixed in (B), and 50 ppm oxygen was mixed in (C), respectively.

As is apparent from above, by using N₂ (nitrogen) as atmospheric gas which is mixed with a small amount of O₂ (oxygen) at a concentration of less than 100 ppm, a thicker oxynitride film could be formed on the surface of the silicon wafer 6, as shown in FIGS. 4(B) and 4(C), compared to that shown in FIG. 4(A) (only N₂). In other words, with the existence of a small amount of O₂, reaction could be enhanced, and heat treatment could be performed at a lower temperature. At the same time, as a thicker oxynitride film was formed, the number of silicon atoms reacting with nitrogen increased, resulting in that the amount of vacancies which could be implanted inside the silicon wafer increased. Consequently, vacancies could be implanted inside the silicon wafer efficiently even without using harmful gas such as NH₃ as atmospheric gas.

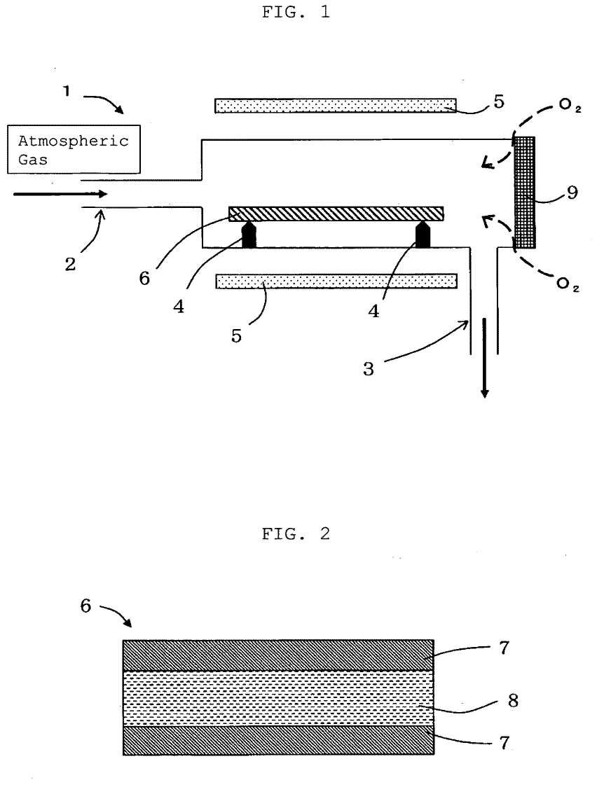

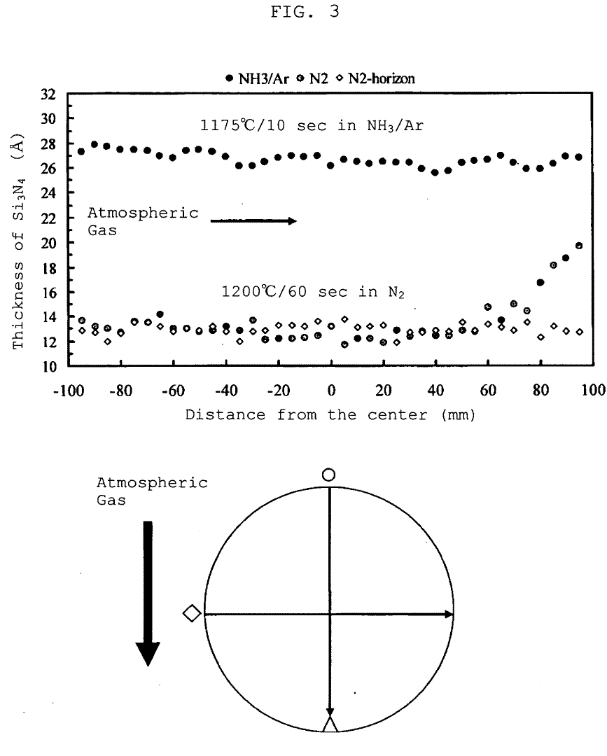

Accordingly, by the subsequent thermal treatment a high-quality wafer with sufficiently thick denuded zones 7 on the surfaces of the silicon wafer and with a BMD zone 8 having an adequately high BMD density inside could be obtained. FIG. 2 schematically shows a silicon wafer to be produced finally. The silicon wafer 6 includes denuded zones 7 on its surfaces and a BMD zone 8 inside.

On the contrary, in the example shown in FIG. 4(A), in which oxygen was not mixed in the nitrogen gas atmosphere, a nitride film was formed slightly only at the gas downstream side. In other words, nitriding reaction of the silicon wafer did not proceed very much at 1200° C.

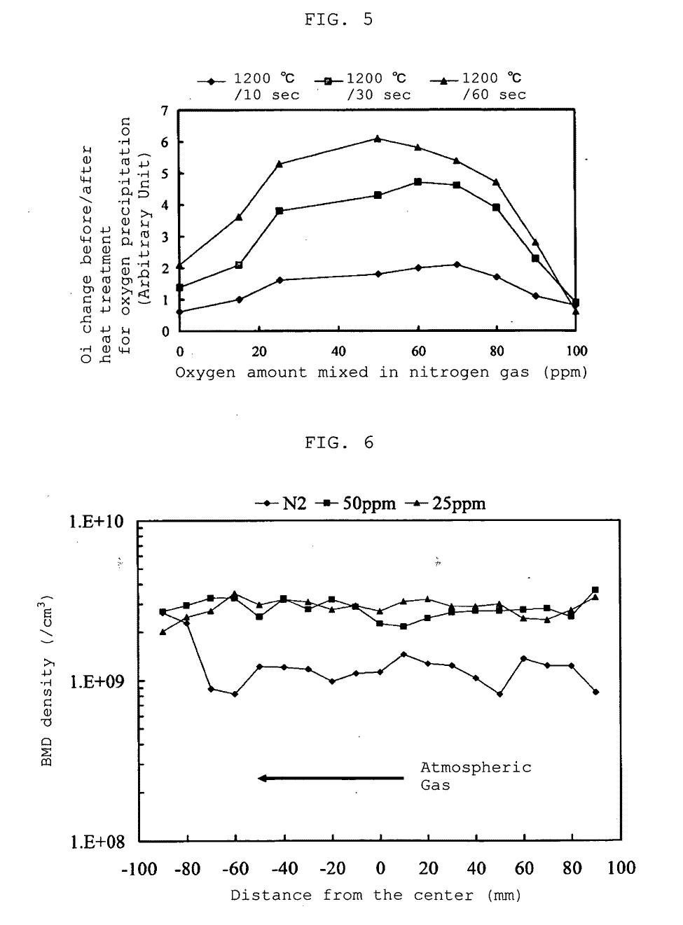

Next, in order to investigate an adequate amount of O₂ to be mixed and an adequate heat treatment time period, tests were conducted by varying the mixed amount of O₂ and the heat treatment time period. FIG. 5 is a graph showing an amount of precipitated oxygen by changing the oxygen amount mixed in nitrogen gas atmosphere from 0 ppm to 100 ppm. It is apparent that by setting the mixed oxygen concentration in nitrogen gas atmosphere to be 15 ppm to 90 ppm, the amount of precipitated oxygen of the silicon wafer was remarkably increased after heat treatment for oxygen precipitation. It is also apparent that enough amount of precipitated oxygen can be obtained by the heat treatment at 1200° C. for 60 seconds. In other words, although the temperature more than 1250° C. was necessary in a conventional method with an atmosphere only containing N₂, in the present invention enough oxide precipitates can be obtained even under 1250° C.

In the case oxygen is mixed in the nitrogen gas atmosphere at a concentration of 100 ppm or above, an oxide film (SiO₂) would be formed on the surface of the silicon wafer, so that interstitial silicon instead of vacancies would be implanted in the silicon wafer, resulting in suppressing the amount of precipitated oxygen. In the case that a small amount of oxygen is mixed in the nitrogen gas atmosphere at a concentration below 100 ppm, a thick oxynitride film can be formed on the surface of silicon wafer 6, so that the amount of precipitated oxygen is not suppressed.

In the case that harmful gas such as NH₃ was used as atmospheric gas, processes took long because it took time for purging step and the like, which was one of the problems. In the present invention, however, as only a small amount, i.e., less than 100 ppm, of O₂ is mixed in nitrogen gas atmosphere, without using harmful gas, processes can be made simple, and the time for purging and the like can be saved. Additionally as this method does not employ harmful gas such as NH₃ or the like, a conventional furnace for RTA heat treatment can be used, i.e., no additional equipment is necessary, so that no additional equipment cost is generated. Therefore, cost reduction can be realized in the both aspects.

Furthermore, as mentioned above, the RTA heat treatment is preferably performed at 1100° C. to 1250° C., and over a period of time 1 to 60 sec. By setting as above, generation of slip dislocation can be suppressed, and at the same time vacancies can be efficiently implanted inside the silicon wafer, so that a BMD zone 8 with an adequately high density can be obtained. In a conventional high-temperature heat treatment, as vacancies and interstitial silicon are generated at the same time, vacancies implanted at RTA heat treatment and the interstitial silicon annihilate each other, so that density of vacancies actually contributing precipitation is reduced. In this invention, however, as temperature at RTA heat treatment is set to be from 1100° C. to 1250° C., the generation of slip dislocation can be avoided and simultaneously the generation of interstitial silicon can be suppressed, so that vacancies can be implanted efficiently inside the silicon wafer.

It is also preferable that oxygen concentration of the silicon wafer before being subject to the RTA heat treatment, i.e., before being fed into the heat treatment furnace 1 is set to be from 9 ppma to 12 ppma. When such a silicon wafer is subject to RTA heat treatment of the present invention where a small amount of oxygen is mixed in nitrogen gas atmosphere, the amount of precipitated oxygen after heat treatment for oxygen precipitation can be made 2 ppma to 5 ppma, so that generation of slip dislocation can be suppressed. Accordingly, a high-quality wafer with sufficient denuded zones 7 on the silicon wafer 6 surfaces and a BMD zone 8 having an adequately high BMD density inside can be obtained by the subsequent thermal treatment.

Note that the amount of precipitated oxygen can be calculated from the difference between the oxygen concentration of the silicon wafer Oi (interstitial oxygen) after RTA heat treatment before heat treatment for oxygen precipitation, and the residual Oi of the silicon wafer after the heat treatment for oxygen precipitation.

In the present examples, as the heat treatment for oxygen precipitation three-stage heat treatment (first stage: 600° C. for 2 hours, second stage: 800° C. for 4 hours, the third stage: 1000° C. for 16 hours) was performed for measuring BMD density. But any method is acceptable as far as it can form denuded zones 7 on the surfaces of the silicon wafer 6 and a BMD zone 8 inside, which would be formed by a heat treatment during a device production process after wafer processing process.

The present invention will be described in detail below with reference to examples of the present invention. The present invention is not limited to these examples, though.

### Example 1

By varying a concentration of oxygen mixed with nitrogen gas as atmospheric gas in the range of above 0 ppm and below 100 ppm, a silicon wafer was subject to RTA heat treatment at a temperature of 1200° C. for a time period of 10 seconds, 30 seconds and 60 seconds, respectively. Then, heat treatment for oxygen precipitation was performed and residual Oi before and after the heat treatment for oxygen precipitation was measured so as to investigate the amount of precipitated oxygen.

The result is shown in FIG. 5. It is apparent from the graph that the amount of precipitated oxygen was increased if the concentration of the oxygen mixed in the nitrogen gas atmosphere was in the range of 15 ppm to 90 ppm. It is also apparent that with longer time period of RTA heat treatment, the amount of precipitated oxygen was increased. Especially, the obtained amount of precipitated oxygen could be tripled in the case of mixed amount of oxygen being 50 ppm, the temperature being 1200° C. and the time period being 60 seconds, compared to the case using only N₂.

### Example 2

A silicon wafer was subject to RTA heat treatment, in which oxygen at a concentration of 25 ppm was mixed with nitrogen gas as atmospheric gas.

The RTA heat treatment here was performed under a condition of temperature of 1200° C. and of a time period of 10 seconds.

Next, for investigating a BMD zone formed by the subsequent heat treatment, three-stage heat treatment was performed so as to measure BMD density.

When an oxynitride film formed on the surface of the silicon wafer through RTA heat treatment was observed by XRT, it was apparent that the oxynitride film was formed on the entire surface of the silicon wafer (See FIG. 4(B)).

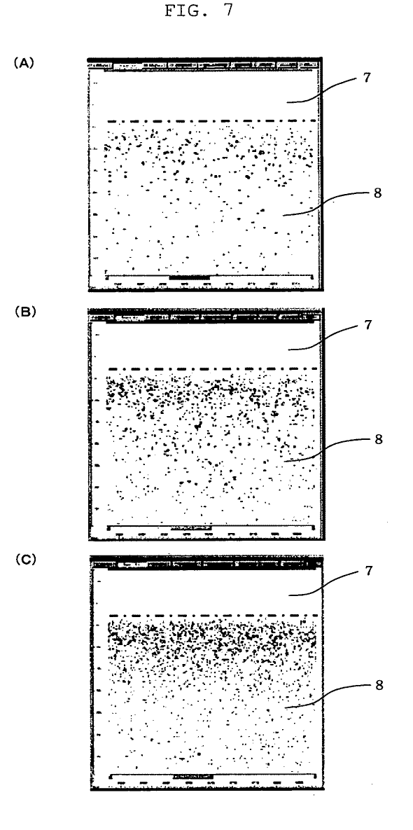

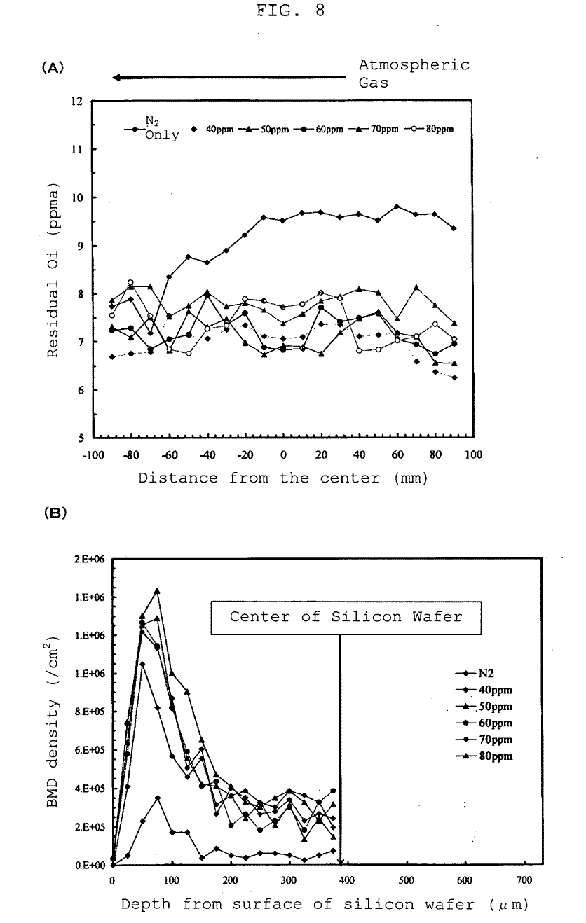

The BMD zone formed inside the silicon wafer after the three-stage heat treatment is shown in FIG. 7(B). BMD density was measured, and the result is shown in FIG. 6.

### Example 3

A silicon wafer was subject to RTA heat treatment, in which oxygen at a concentration of 50 ppm was mixed with nitrogen gas as atmospheric gas.

The RTA heat treatment here was performed under a condition of temperature of 1200° C. and of a time period of 10 seconds.

Next, for investigating a BMD zone formed by the subsequent heat treatment, three-stage heat treatment was performed so as to measure BMD density.

When an oxynitride film formed on the surface of the silicon wafer through RTA heat treatment was observed by XRT, it was apparent that the oxynitride film was formed almost on the entire surface of the silicon wafer (See FIG. 4(C)).

The BMD zone formed inside the silicon wafer after the three-stage heat treatment is shown in FIG. 7(C). BMD density was measured, and the result is shown in FIG. 6.

### Example 4

A silicon wafer, which has a oxygen concentration of 11.3 ppma to 11.7 ppma prior to being fed into the heat treatment furnace, was subject to RTA heat treatment, in which oxygen was mixed with nitrogen gas as atmospheric gas at a concentration of 40 ppm to 80 ppm.

The RTA heat treatment here was performed under a condition of temperature of 1200° C. and of a time period of 30 seconds.

The result is shown in FIG. 8. When oxygen was mixed at 40 ppm to 80 ppm, residual Oi was, as shown in FIG. 8(A), in the range of about 6.2 ppma to 8.3 ppma, from which it was apparent that the amount of precipitated oxygen was homogenous in the range of 3 ppma to 5.5 ppma in the entire wafer surface. Furthermore, from FIG. 8(B), vacancies were implanted in this example at a higher amount in the depth about 80 μm from the surface of the silicon wafer.

### Comparative Example 1

Employing only nitrogen gas as atmospheric gas, a silicon wafer was subject to RTA heat treatment at a temperature of 1200° C. and for a time period of 10 seconds, 30 seconds and 60 seconds, respectively.

Then, heat treatment for oxygen precipitation was performed so as to investigate the amount of precipitated oxygen.

As a result, it was apparent that the amount of precipitated oxygen was very small. It was also apparent from FIG. 5 that the amount of precipitated oxygen was greater in the case that oxygen was mixed at a concentration less than 100 ppm compared to the case that only nitrogen gas was applied as atmospheric gas (i.e. mixed oxygen amount is 0 ppm).

### Comparative Example 2

A silicon wafer was subject to RTA heat treatment, in which only nitrogen gas was applied as atmospheric gas.

The RTA heat treatment here was performed under a condition of temperature of 1200° C. and of a time period of 10 seconds.

Next, for investigating a BMD zone formed by the subsequent heat treatment, three-stage heat treatment was performed and then BMD density was measured.

When an oxynitride film formed on the surface of the silicon wafer through RTA heat treatment was observed by XRT, it was apparent that a nitride film was slightly formed only on the gas outlet side of the silicon wafer (See FIG. 4(A)).

The BMD zone formed inside the silicon wafer after the three-stage heat treatment is shown in FIG. 7(A). BMD density was measured, and the result is shown in FIG. 6.

A nitride film and an oxynitride film formed on the surface of the silicon wafer are compared in FIGS. 4(A) to 4(C). When atmospheric gas contained only nitrogen gas, an oxynitride film was formed slightly only on the gas outlet side due to assumingly gas leakage. When a small amount of oxygen was mixed with nitrogen gas, a thick oxynitride film was formed on the entire surface of the silicon wafer, as shown in FIGS. 4(B) and 4(C).

FIG. 6 is a graph showing BMD density measured after RTA heat treatment (temperature of 1200° C. and time period of 10 seconds) followed by three-stage heat treatment with respect to the case that no oxygen was mixed with nitrogen gas atmosphere (Comparative Example 2), the case that 25 ppm oxygen was mixed (Example 2) and the case that 50 ppm oxygen was mixed (Example 3), respectively.

Comparing BMD density in the BMD zone in FIG. 6, it is apparent that the BMD density was exceptionally high, i.e., about 3.0×10⁹/cm³ only at the gas outlet side in the case of only nitrogen being employed as atmospheric gas, while in other regions it was about 0.8×10⁹/cm³ to about 1.5×10⁹/cm³. In the case that a small amount of oxygen was mixed into the nitrogen gas, BMD density was about 2.0×10⁹/cm³ to about 4.0×10⁹/cm³, so that a BMD zone with high density was obtained in the entire surface of the wafer.

FIG. 7 shows the observation result on the cross-section of the wafer at the time of the measurement of FIG. 6. From this FIG. the size and density of BMD (black spots) can be confirmed with respect to FIG. 7 (A) the case that no oxygen was mixed in nitrogen gas atmosphere (Comparative Example 2), FIG. 7 (B) the case that 25 ppm oxygen was mixed (Example 2) and FIG. 7 (C) the case that 50 ppm oxygen was mixed (Example 3), respectively.

From FIG. 7, it is apparent that the BMDs have smaller sizes and are located more densely in the cases of (B) and (C), where a small amount of oxygen was mixed in the nitrogen gas atmosphere, compared to the case of (A), where only nitrogen gas was employed as atmospheric gas.

Accordingly, by using nitrogen gas as the atmospheric gas at RTA heat treatment, which is mixed with a small amount of oxygen at a concentration of less than 100 ppm, it is possible to form a thick oxynitride film on the surface of the silicon wafer, so that vacancies can be implanted inside the silicon wafer efficiently. Then, by the subsequent thermal treatment a high-quality wafer including a BMD zone with small BMDs and an adequately high BMD density can be obtained.

### Comparative Example 3

A silicon wafer was subject to RTA heat treatment, in which only N₂ gas, only Ar gas, mixed gas with NH₃ and Ar, and mixed gas with NH₃ and N₂ gas were employed as atmospheric gas, respectively.

The RTA heat treatment here was performed under a condition of temperature of 1200° C. and of a time period of 10 seconds.

Next, for investigating a BMD zone formed by the subsequent heat treatment, three-stage heat treatment was performed so as to measure BMD density.

Measurement result of BMD density with respect to Example 3 and Comparative Example 3 is shown in Table 1. When atmospheric gas contains only N₂ or Ar, BMD density was limited up to 5×10⁸/cm³. When mixed gas with NH₃ and Ar, or mixed gas with NH₃ and N₂ gas was used, a BMD zone with high density such as 2×10⁹/cm³ was formed. When a small amount of oxygen was mixed into the nitrogen gas atmosphere as in the case of the present invention, a BMD zone with high density such as 2×10⁹/cm³ could be formed similarly as in the case of conventional methods using harmful NH₃ gas in the atmospheric gas. Therefore, in the present invention, even though harmful gas such as NH₃ is not used as atmospheric gas, a high-quality silicon wafer having a BMD zone with adequately high density can be obtained by way of heat treatment with low-temperature over a short time period.

TABLE 1

| | Atmospheric Gas | BMD Density |
|---|---|---|
| Example 3 | N2 + Slight Amount O2 | >2E9/cm3 |
| | (50 ppm) | |
| Comperative Example 3 | NH3 + Ar | >2E9/cm3 |
| Comperative Example 3 | NH3 + N2 | >2E9/cm3 |
| Comperative Example 3 | N2 only | up to 5E8/cm3 |
| Comperative Example 3 | Ar only | up to 1E8/cm3 |

### Comparative Example 4

A silicon wafer, which had a oxygen concentration of 11.3 ppma to 11.7 ppma prior to being fed into the heat treatment furnace, was subject to RTA heat treatment, in which nitrogen gas was applied as atmospheric gas.

The RTA heat treatment here was performed under a condition of a temperature of 1200° C. and of a time period of 30 seconds.

FIG. 8 shows the result of Example 4 and Comparative Example 4. FIG. 8(A) is a graph showing a relation between residual Oi amount and its distance from the center of the silicon wafer. FIG. 8(B) is a graph showing a relation between BMD density and its depth from the surface of the silicon wafer. With reference to FIG. 8(A), residual Oi was in the range of about 9 ppma to 10 ppma when the atmospheric gas contained only N₂. As the initial oxygen concentration was about 11 ppm, it was apparent that, the amount of precipitated oxygen was about 1 ppma to 2 ppma, and that the amount of precipitated oxygen was less compared to the case that a small amount of oxygen was mixed in the nitrogen atmospheric gas. It is also apparent from FIG. 8(B) that BMD density was lower in the case compared to the case that a small amount of oxygen was mixed in the nitrogen atmospheric gas. In the present example, on the contrary, oxygen was precipitated homogenously in the entire wafer surface, and in the depth direction, a BMD zone with high-density could be obtained immediately under surface zone, so that a high gettering effect could be expected.

The present invention is not limited to the above-described embodiments. The above-described embodiments are mere examples, and those having the substantially same constitution as that described in the appended claims and providing the similar action and advantages are included in the scope of the present invention.

1. A method for producing a silicon wafer at least including a step of performing RTA heat treatment with respect to a silicon wafer in an atmospheric gas, wherein nitrogen gas is used as the atmospheric gas, which is mixed with oxygen at a concentration of less than 100 ppm so as to perform the heat treatment.

2. The method for producing a silicon wafer according to claim 1, wherein the concentration of the oxygen mixed in the nitrogen gas atmosphere is set to be from 15 ppm to 90 ppm.

3. The method for producing a silicon wafer according to claim 1, wherein the heat treatment is performed at a temperature of 1100° C. or more and 1250° C. or less.

4. The method for producing a silicon wafer according to claim 1, wherein the heat treatment is performed for 1 to 60 sec.

5. The method for producing a silicon wafer according to claim 1, wherein oxygen concentration of the silicon wafer before being subject to the heat treatment is set to be from 9 ppma to 12 ppma (JEITA).

6. The method for producing a silicon wafer according to claim 2, wherein the heat treatment is performed at a temperature of 1100° C. or more and 1250° C. or less.

7. The method for producing a silicon wafer according to claim 2, wherein the heat treatment is performed for 1 to 60 sec.

8. The method for producing a silicon wafer according to claim 3, wherein the heat treatment is performed for 1 to 60 sec.

9. The method for producing a silicon wafer according to claim 6, wherein the heat treatment is performed for 1 to 60 sec.

10. The method for producing a silicon wafer according to claim 2, wherein oxygen concentration of the silicon wafer before being subject to the heat treatment is set to be from 9 ppma to 12 ppma (JEITA).

11. The method for producing a silicon wafer according to claim 3, wherein oxygen concentration of the silicon wafer before being subject to the heat treatment is set to be from 9 ppma to 12 ppma (JEITA).

12. The method for producing a silicon wafer according to claim 6, wherein oxygen concentration of the silicon wafer before being subject to the heat treatment is set to be from 9 ppma to 12 ppma (JEITA).

13. The method for producing a silicon wafer according to claim 4, wherein oxygen concentration of the silicon wafer before being subject to the heat treatment is set to be from 9 ppma to 12 ppma (JEITA).

14. The method for producing a silicon wafer according to claim 7, wherein oxygen concentration of the silicon wafer before being subject to the heat treatment is set to be from 9 ppma to 12 ppma (JEITA).

15. The method for producing a silicon wafer according to claim 8, wherein oxygen concentration of the silicon wafer before being subject to the heat treatment is set to be from 9 ppma to 12 ppma (JEITA).

16. The method for producing a silicon wafer according to claim 9, wherein oxygen concentration of the silicon wafer before being subject to the heat treatment is set to be from 9 ppma to 12 ppma (JEITA).
